(19) United States
(12) Patent Application Publication
(10) Pub. No.: US 2020/0029466 A1
(43) Pub. Date: Jan. 23, 2020

(54) LIQUID-HEAT-TRANSMISSION DEVICE

(71) Applicants: Ling LONG, Shanghai (CN); Haixia WANG, Shanghai (CN); Tonghu XIA, Shanghai (CN); Shanghai LuYao Energy Technology Co., Ltd., Shanghai (CN)

(72) Inventors: Ling LONG, Shanghai (CN); Haixia WANG, Shanghai (CN); Tonghu XIA, Shanghai (CN)

(21) Appl. No.: 16/039,295

(22) Filed: Jul. 18, 2018

(51) Int. Cl. H05K 7/20

(52) U.S. Cl. CPC H05K 7/20309; H05K 7/20436; H05K 7/20336

(57) ABSTRACT

A liquid-heat-transmission device includes a vapor chamber, a cover, and a channel structure. The cover covers on a surface of the vapor chamber and a flow chamber is defined thereby. A water inlet and a water outlet respectively communicated with the flow chamber are defined on the cover. The channel structure is arranged in the flow chamber. The flow channel structure includes multiple fins arranged between the water inlet and the water outlet and with an interval apart. Each fin is extended in a longitudinal direction on a surface of the vapor chamber and connected to the vapor chamber and the cover. The vapor chamber is attached to a heat source, and a working fluid flows through the flow chamber from the water inlet of the cover and is drained after fully exchanging heat with the vapor chamber.

### FIELD OF THE INVENTION

This disclosure relates to a liquid-heat-transmission device used in liquid-cooling systems and more particularly to a liquid-heat-transmission device with a vapor chamber integrated with a channel structure.

### BACKGROUND OF THE INVENTION

In general, heat is generated during the operation of high-performance electronic devices, and the heat cannot be dissipated timely just by using fans, so that a liquid-cooling heat sink is usually added to the high-performance electronic devices. The conventional liquid-cooling heat sink generally includes a water cooling head and a circulation pipeline communicated to the water cooling head, and the circulation pipeline is filled with a working fluid, and the water cooling head is in contact with a heat source in the electronic device, and the working fluid passes through the water cooling head and the heat source for a heat exchange. To lower the temperature of the working fluid, an increase of the flux of the working fluid is helpful to cool down the cooling liquid, but the heat exchange of the system is still limited by the thermal resistance between the water cooling head and the heat source.

In view of the aforementioned drawbacks of the prior art, the discloser of this disclosure based on years of experience to conduct extensive research and experiment, and finally provided a feasible solution to overcome the drawbacks of the prior art.

### SUMMARY OF THE INVENTION

Therefore, it is a primary objective of this disclosure to provide a liquid-heat-transmission device with a vapor chamber integrated with a channel structure.

To achieve the aforementioned and other objectives, this disclosure provides a liquid-heat-transmission device, comprising a vapor chamber, a cover, and a channel structure. The cover is covered onto one of the sides of the vapor chamber and enclosed to form a flow chamber, and the cover has a water inlet and a water outlet disposed thereon and communicated to the flow chamber. The channel structure is installed in the flow chamber and disposed between the water inlet and the water outlet.

The channel structure comprises a plurality of fins arranged with an interval apart from one another and disposed between the water inlet and the water outlet, and each of the fins is extended longitudinally along a surface of the vapor chamber, and the fins are coupled to the vapor chamber and the cover respectively.

In the liquid-heat-transmission device of this disclosure, each of the fins has a pair of side edges configured to be opposite to each other and coupled to the vapor chamber and the cover respectively. Each fin is protruded and formed on a surface of the vapor chamber and transversely projected to touch the cover. Each fin may be protruded and formed on a surface of the cover and transversely projected to touch the vapor chamber.

In the liquid-heat-transmission device of this disclosure, each of the fins has both ends configured to be apart from the inner walls of the cover respectively. The fins have a plurality of shunt channels formed at the inner periphery of the flow chamber and communicating between the water inlet and the water outlet.

In the liquid-heat-transmission device of this disclosure, each of the fins has both ends coupled to a connection end on the inner wall of the cover and a disconnection end configured to be apart from the inner wall of the cover respectively. The connection ends and the disconnection ends of the fins are arranged in an interspersed manner. The fins have a single flow channel formed at the inner periphery of the flow chamber and communicating between the water inlet and the water outlet.

In the liquid-heat-transmission device of this disclosure, the cover has a trench formed at an outer edge of the cover and surrounding the flow chamber, and a sealing ring embedded into the trench and clamped between the vapor chamber and the cover.

In the liquid-heat-transmission device of this disclosure, the vapor chamber is hollow inside and has a capillary structure installed therein. The vapor chamber is hollow inside and has a plurality of support columns disposed therein and coupled between both sides of the vapor chamber and penetrating through the capillary structure. The channel structure has a plurality of shunt channels formed at the inner periphery of the flow chamber and communicating between the water inlet and the water outlet. The channel structures may have a single flow channel formed at the inner periphery of the flow chamber and communicating between the water inlet and the water outlet.

In the liquid-heat-transmission device of this disclosure, the vapor chamber is attached closely to a heat source, and the working fluid flows from the water inlet of the cover through the single flow channel or the shunt channel and exchanges heat with the vapor chamber sufficiently before flowing to the outside.

### BRIEF DESCRIPTION OF THE DRAWINGS

FIGS. 1 to 3 are schematic views of a liquid-heat-transmission device in accordance with a first embodiment of this disclosure; and

FIG. 4 is a schematic view of a liquid-heat-transmission device in accordance with a second embodiment of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and figures disclosed herein are to be considered illustrative rather than restrictive.

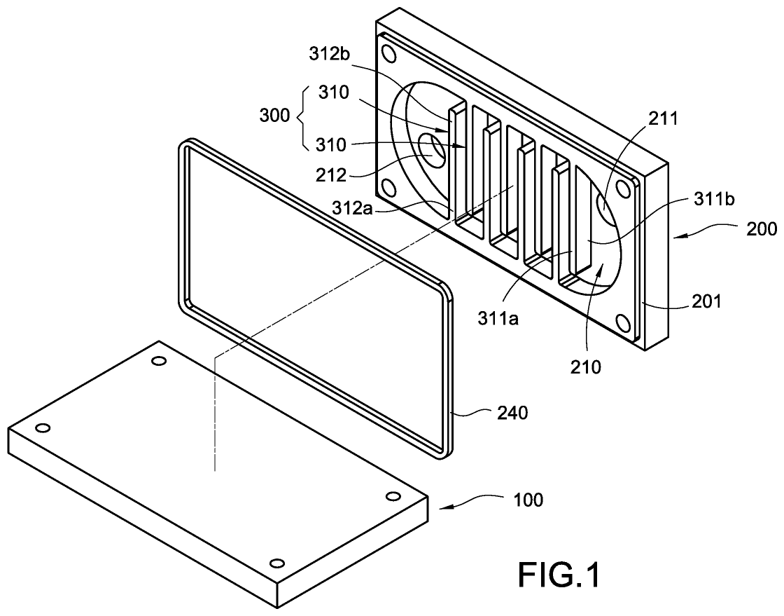

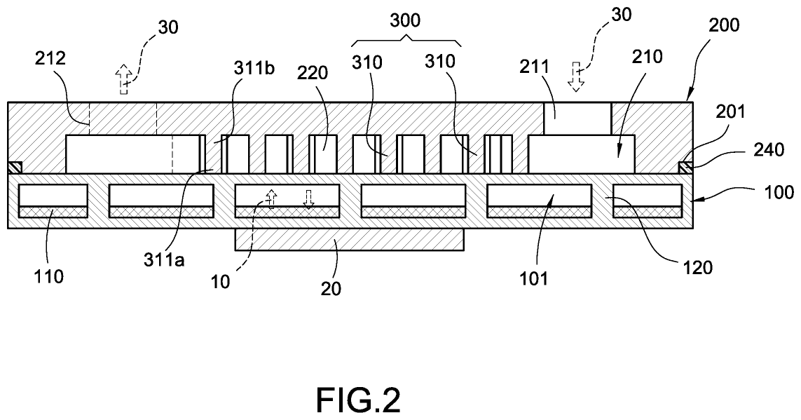

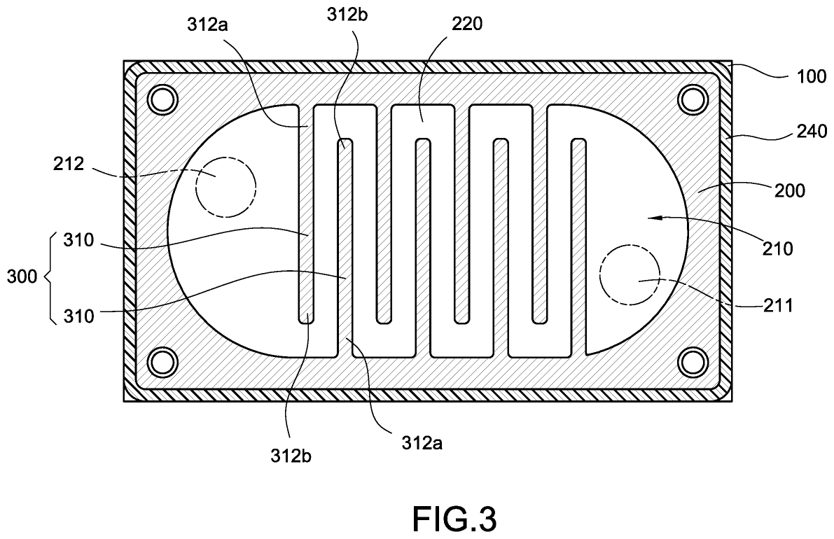

With reference to FIGS. 1 to 3 for a liquid-heat-transmission device in accordance with a first embodiment of this disclosure, the liquid-heat-transmission device comprises a vapor chamber 100, a cover 200, and a channel structure 300. In the liquid-heat-transmission device of this disclosure, the vapor chamber 100 is a hollow plate and the vapor chamber 100 has a capillary structure 110 installed therein, and the capillary structure 110 is preferably mesh shaped. The vapor chamber 100 further comprises a plurality of support columns 120 installed and coupled between both sides of the vapor chamber 100 to maintain the external structural shape of the vapor chamber 100, wherein each support column 120 can penetrate through each respective capillary structure 110, but this disclosure is not limited to such arrangement only. The vapor chamber 100 is provided for accommodating a circulating fluid 10, and the liquid-state circulating fluid 10 is adsorbed into the capillary structure 110. One side of the vapor chamber 100 is in contact with a heat source 20 to input heat energy, and the liquid-state circulating fluid 10 is vaporized after absorbing the heat of the heat source 20, and the gaseous circulating fluid 10 flows towards the other side of the vapor chamber 100 to conduct the heat to the other side of the vapor chamber 100 for its output. The gaseous circulating fluid 10 is sucked into the capillary structure 110 after being cooled and liquefied, and the circulating fluid 10 repeats the phase change in the vapor chamber 100. The cover 200 covers on a heat outputting side of the vapor chamber 100 to enclose and form a flow chamber 210 for passing a working fluid 30 in order to exchange heat with the heat outputting side. A trench 201 is formed at the outer edge of the cover 200 and surrounds the flow chamber 210, and a sealing ring 240 is embedded into the trench 201 and clamped between the vapor chamber 100 and the cover 200 to seal the flow chamber 210. It is noteworthy that this disclosure is not limited to the aforementioned arrangement only, but the vapor chamber 100 and the cover 200 may be integrally coupled without requiring the sealing ring 240. The cover 200 has a water inlet 211 communicated with the flow chamber 210 and provided for flowing the working fluid 30 into the flow chamber 210 and a water outlet 212 provided for flowing the working fluid 30 out from the flow chamber 210. After the working fluid 30 passes through the water outlet 212 and flows out from the flow chamber 210, the working fluid 30 passes through the water inlet 211 after being cooled and then circulates and flows into the flow chamber 210. It is noteworthy that this disclosure is not limited to such arrangement only, but the working fluid 30 may pass through the water outlet 212 and flow out from the flow chamber 210 without refluxing. In other words, the working fluid 30 is discharged directly.

The channel structure 300 is disposed in the flow chamber 210 and includes a plurality of fins 310 arranged with an interval apart from one another and disposed between the water inlet 211 and the water outlet 212, and each fin 310 is extended longitudinally along a surface of the vapor chamber 100. In this embodiment, each fin 310 preferably has a pair of side edges 311a/311b configured to be opposite to each other and coupled to the vapor chamber 100 and the cover 200 respectively, and each fin 310 is preferably protruded and formed on an inner surface of the cover 200 and transversely projected to touch the vapor chamber 100, so that the side edges 311a/311b are coupled to the vapor chamber 100 and the cover 200 respectively.

In this embodiment, both ends of each fin 310 are coupled to a connection end 312a on an inner wall of the cover 200 and a disconnection end 312b configured with an interval apart from the inner wall of the cover 200 respectively. The connection end 312a and disconnection end 312b of the fin 310 are arranged in an interspersed manner. The fin 310 has a single flow channel 220 formed at the inner periphery of the flow chamber 210 and communicating between the water inlet 211 and the water outlet 212 and extended tortuously along a surface of the vapor chamber 100.

The working fluid 30 passes through the water inlet 211 and enters into the flow chamber 210 and then passes through the single flow channel 220 and flows tortuously through the surface of the vapor chamber 100 to exchange heat with the vapor chamber 100. Finally, the working fluid 30 is passed through the water outlet 212 and discharged from the flow chamber 210 to the outside.

In the liquid-heat-transmission device of this disclosure, the fin 310 guides the working fluid 30 to flow from the water inlet 211 towards the water outlet 212 and pass through the vapor chamber 100 to exchange heat with the vapor chamber 100. Compared with the traditional thermal conduction and convection, the vapor chamber 100 of this disclosure transmits heat through a phase change to expedite the transmission of the heat of the heat source 20 to the working fluid 30.

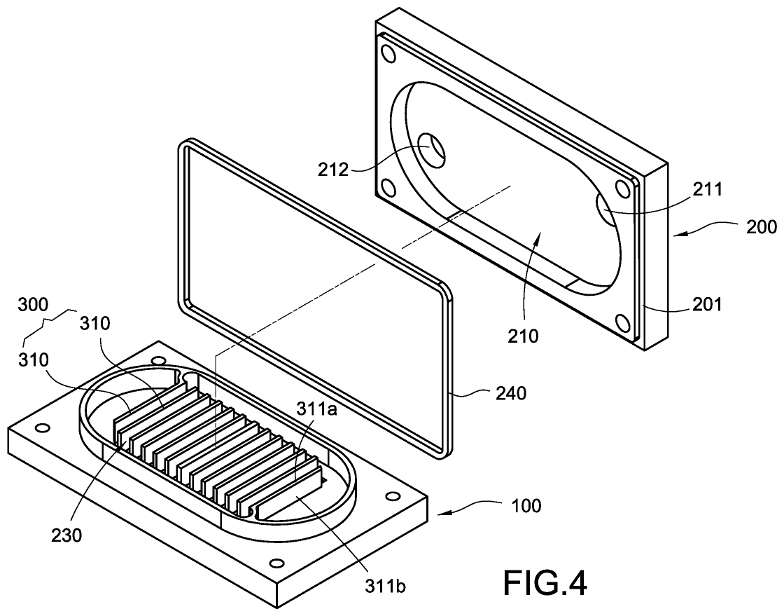

With reference to FIG. 4 for a liquid-heat-transmission device in accordance with the second embodiment of this disclosure, the liquid-heat-transmission device comprises a vapor chamber 100, a cover 200, and a channel structure 300. The cover 200 covers on one of the sides of the vapor chamber 100 to enclose and form a flow chamber 210, and the cover 200 has a water inlet 211 and a water outlet 212 formed thereon and communicating to the flow chamber 210. The channel structure 300 is installed in the flow chamber 210 and comprises a plurality of fins 310 having an interval apart from one another and disposed between the water inlet 211 and the water outlet 212. Each fin 310 is extended longitudinally along a surface of the vapor chamber 100 and each fin 310 has a pair of side edges 311a/311b configured to be opposite to each other and coupled to the vapor chamber 100 and the cover 200 respectively.

The structure of this embodiment is substantially the same as that of the first embodiment, except that each fin 310 of this embodiment is protruded and formed on a surface of the vapor chamber 100 and transversely projected to touch the cover 200, and both ends of each fin 310 are configured to be apart from the inner walls of the cover 200 respectively. Therefore, the fin 310 has a plurality of shunt channels 230 formed at the inner periphery of the flow chamber 210 and communicated between the water inlet 211 and the water outlet 212.

The working fluid 30 passes through the water inlet 211 and enters into the flow chamber 210, and then passes through each shunt channel 230 and flows through the surface of the vapor chamber 100 to exchange heat with the vapor chamber 100. Finally, the working fluid 30 is passed through the water outlet 212 and discharged from the flow chamber 210 to the outside.

While this disclosure has been described by means of specific embodiments, numerous modifications and variations could be made thereto by those skilled in the art without departing from the scope and spirit of this disclosure set forth in the claims.

1. A liquid-heat-transmission device, comprising:
a vapor chamber;
a cover, having a bottom plane surface covered onto one of the surfaces of the vapor chamber to enclose and form a flow chamber, and having a water inlet and a water outlet both disposed on a top surface thereof and communicated to the flow chamber; and
a channel structure, installed in the flow chamber, and disposed between the water inlet and the water outlet,
wherein the channel structure comprises a plurality of fins arranged with an interval apart from one another, and each of the fins is extended longitudinally along a surface of the vapor chamber;
wherein each of the fins has a pair of side edges configured to be opposite to each other and coupled to the vapor chamber and the cover respectively;
wherein all side edges of the fins that are coupled to the vapor chamber have surfaces flush with the bottom plane surface of the cover.

2. (canceled)

3. (canceled)

4. The liquid-heat-transmission device of claim 1, wherein each of the fins is protruded and formed on a surface of the vapor chamber and transversely projected to touch the cover.

5. The liquid-heat-transmission device of claim 1, wherein each of the fins is protruded and formed on a surface of the cover and transversely projected to touch the vapor chamber.

6. The liquid-heat-transmission device of claim 1, wherein each of the fins has both ends configured to be apart from the inner walls of the cover respectively.

7. The liquid-heat-transmission device of claim 5, wherein the fins have a plurality of shunt channels formed at the inner periphery of the flow chamber and communicating between the water inlet and the water outlet.

8. The liquid-heat-transmission device of claim 1, wherein each of the fins has both ends coupled to a connection end on the inner wall of the cover and a disconnection end configured to be apart from the inner wall of the cover respectively.

9. The liquid-heat-transmission device of claim 8, wherein the connection ends and the disconnection ends of the fins are arranged in an interspersed manner.

10. The liquid-heat-transmission device of claim 9, wherein the fins have a single flow channel formed at the inner periphery of the flow chamber and communicating between the water inlet and the water outlet.

11. The liquid-heat-transmission device of claim 1, wherein the cover has a trench formed at an outer edge of the cover and surrounding the flow chamber, and a sealing ring embedded into the trench and clamped between the vapor chamber and the cover.

12. The liquid-heat-transmission device of claim 1, wherein the vapor chamber is hollow inside and has a capillary structure installed therein.

13. The liquid-heat-transmission device of claim 12, wherein the vapor chamber is hollow inside and has a plurality of support columns disposed therein and coupled between both sides of the vapor chamber and penetrating through the capillary structure.

14. The liquid-heat-transmission device of claim 1, wherein the vapor chamber is hollow inside and has a plurality of support columns disposed therein and coupled between both sides of the vapor chamber.

15. The liquid-heat-transmission device of claim 1, wherein the channel structure has a plurality of shunt channels formed at the inner periphery of the flow chamber and communicating between the water inlet and the water outlet.

16. The liquid-heat-transmission device of claim 1, wherein the channel structures have a single flow channel formed at the inner periphery of the flow chamber and communicating between the water inlet and the water outlet.
